(19) United States
(12) Patent Application Publication
(10) Pub. No.: US 2022/0206389 A1
(43) Pub. Date: Jun. 30, 2022

(54) STRUCTURE FOR OPTICAL DEVICES, PROCESS FOR PREPARING THE SAME, AND PHOTOCURABLE SILOXANE RESIN COMPOSITION THEREFOR

(71) Applicant: ROHM AND HAAS ELECTRONIC MATERIALS KOREA LTD., Chungcheongnam-do (KR)

(72) Inventors: Hyung-Tak JEON, Gyeonggi-do (KR); Ji-Ung KIM, Gyeonggi-do (KR); Seung-Kyu SONG, Gyeonggi-do (KR); Geun HUH, Gyeonggi-do (KR)

(21) Appl. No.: 17/549,806

(22) Filed: Dec. 13, 2021

(30) Foreign Application Priority Data
Dec. 28, 2020 (KR) 10-2020-0184356
Nov. 30, 2021 (KR) 10-2021-0168678

(51) Int. Cl. G03F 7/075; G03F 7/004; G03F 7/20

(52) U.S. Cl. CPC G03F 7/0757; G03F 7/2004; G03F 7/0045

(57) ABSTRACT

The structure for an optical device according to an embodiment comprises a protective layer formed from a photocurable siloxane resin composition, wherein the protective layer is capable of serving not only to protect or seal a light emitting element such as a mini-LED chip from external heat or moisture, but also to improve such optical characteristics as brightness and contrast ratio of light emitted from the light emitting element through the light diffusion effect.

### TECHNICAL FIELD

The present invention relates to a structure for an optical device, a process for preparing the same, and a photocurable siloxane resin composition therefor.

### BACKGROUND ART

An optical device refers to a light emitting element that converts an electrical signal into an optical signal. Typically, light emitting diodes (LEDs) are utilized by virtue of such advantages as high conversion efficiencies of light energy, miniaturization, weight reduction, and low power consumption. In recent years, the size of LED chips is gradually getting smaller. For example, mini-LEDs having a chip size of 100 μm to 200 μm and micro-LEDs having a chip size of less than 100 μm are being developed. Since each LED chip in mini-LEDs and micro-LEDs individually functions as a pixel or light source, restrictions on the size and shape of a display are eliminated, and clearer image quality than those of conventional light sources can be achieved.

Mini-LEDs among the above are based on an intermediate-stage technology between general LEDs and micro-LEDs. Since there is an advantage in that the existing LED production lines may be used, it is possible to increase the profitability while the life span of existing production plants and technology is extended. In particular, mini-LEDs are thinner than organic light emitting diodes (OLEDs) that are currently widely used, can enhance the power efficiency and resolution, and can improve the burn-in phenomenon, which is a disadvantage of OLEDs.

LED chips are wrapped with an encapsulant for protection, which encapsulant serves to protect the LED chips from external heat or moisture. The conventional encapsulants are generally obtained by introducing a thermal acid generator or a thermal base generator to cure an epoxy or by crosslinking a double bond in the presence of a platinum catalyst. However, in these conventional methods, it is difficult to reproduce the shape of a cured product because the heat flow is not controlled during the process, and there is a problem in that it takes a long time for curing or that discoloration may occur depending on the amount of the platinum catalyst used.

In addition, in composite LEDs, a lens for diffusing light is formed on an encapsulant, and such a lens must be formed in a dome structure having a certain level of thickness to facilitate the diffusion of light. In particular, since mini-LEDs have smaller parts to produce light than those of general LEDs, it is necessary to improve the brightness or contrast ratio of light generated from the LED chips through the light diffusion effect of the lenses.

In recent years, a method of encapsulating LED chips and forming lenses using an LED encapsulant is being developed. For this, it is required to have the characteristics of an LED encapsulant and a lens at the same time. However, the conventional encapsulants have a problem in that heat generated from the LED chips increases the temperature of the LED packaging, which lowers the adhesiveness of the encapsulant, or the light efficiency is reduced due to yellowing or decreased transmittance.

### PRIOR ART DOCUMENT

(Patent Document 1) Korean Laid-open Patent Publication No. 2014-0078655

### DISCLOSURE OF INVENTION

### Technical Problem

As a result of the research conducted by the present inventors, a functional group that reacts with an acid is introduced to a polysiloxane, a photoacid generator instead of a thermal acid generator is used, and a solvent-free type photocurable siloxane resin composition with controlled viscosity is used, whereby it is possible to obtain a protective layer with excellent pattern reproducibility and light diffusion characteristics while shortening the curing time.

Accordingly, an object of the present invention is to provide a structure for an optical device provided with a protective layer, which is capable of serving not only to protect or seal a light emitting element such as a mini-LED chip from external heat or moisture, but also serving as a lens to improve such optical characteristics as brightness and contrast ratio of light emitted from the light emitting element through the light diffusion effect.

### Solution to Problem

In order to accomplish the above object, the present invention provides a structure for an optical device, which comprises a substrate layer; a light emitting element formed on the substrate layer; and a protective layer surrounding the light emitting element, wherein the protective layer comprises a photocured material of a photocurable siloxane resin composition.

The process for preparing a structure for an optical device comprises preparing a substrate layer and a light emitting element formed on the substrate layer; applying a photocurable siloxane resin composition to the light emitting element; and irradiating light to the photocurable siloxane resin composition to form a protective layer surrounding the light emitting element.

The photocurable siloxane resin composition comprises (A) a polysiloxane having a functional group that reacts with an acid; (B) a photoacid generator; and (C) a solvent-free type diluent having a functional group that reacts with an acid, wherein the viscosity of the polysiloxane is 10,000 cP to 50,000 cP at 25° C., and the content of the solvent in the composition is less than 4.0% by weight.

### Advantageous Effects of Invention

The structure for an optical device according to the present invention comprises a protective layer formed from a photocurable siloxane resin composition, wherein the protective layer is capable of serving not only to protect or seal a light emitting element such as a mini-LED chip from external heat or moisture, but also to improve such optical characteristics as brightness and contrast ratio of light emitted from the light emitting element through the light diffusion effect attributable to improvement in the refractive index.

Specifically, in the photocurable siloxane resin composition used for the preparation of the protective layer, a functional group that reacts with an acid is introduced to a polysiloxane, and a photoacid generator instead of a thermal acid generator that takes a long time to cure is used, thereby shortening the curing time and satisfying pattern reproducibility and physical properties. In addition, the photocurable siloxane resin composition is a solvent-free type, and the acid generated by light acts as a catalyst to shorten the process time. Since it does not require the use of a platinum catalyst, there is no concern about discoloration due to platinum adsorption during the process. In addition, the photocurable siloxane resin composition has a controlled viscosity, thereby solving the problem that it is difficult for the conventional compositions to increase the thickness due to the heat flow in the direction of gravity. It is also possible to obtain a structure for an optical device provided with a protective layer having an excellent diameter to thickness ratio.

### BRIEF DESCRIPTION OF DRAWINGS

FIG. 1 shows a cross-sectional view of a structure for an optical device according to an embodiment.

FIG. 2 shows the diameter and thickness of a protective layer in the structure for an optical device according to an embodiment.

FIG. 3 shows a process for preparing a structure for an optical device according to an embodiment.

FIG. 4a is a photograph of the protective layer of the Example having an excellent diameter to thickness ratio in the Test Example.

FIG. 4b is a photograph of the protective layer of the Comparative Example having a poor diameter to thickness ratio in the Test Example.

FIG. 5a is a photograph of the protective layer of the Example having an excellent yellow index (Y.I.) in the Test Example.

FIG. 5b is a photograph of the protective layer of the Comparative Example having a poor yellow index in the Test Example.

### REFERENCE NUMERALS OF THE DRAWINGS

| | |
|---|---|
| 10: structure for an optical device | |
| 100: substrate layer | 200: light emitting element |
| 300: protective layer | 301: photocurable siloxane resin |
| | composition |
| D: diameter of a protective layer | t: thickness of the protective layer |

### BEST MODE FOR CARRYING OUT THE INVENTION

The present invention is not limited to those described below. Rather, it can be modified into various forms as long as the gist of the invention is not altered.

Throughout the present specification, when a part is referred to as “comprising” an element, it is understood that other elements may be comprised, rather than other elements are excluded, unless specifically stated otherwise. In addition, all numbers and expressions relating to quantities of components, reaction conditions, and the like used herein are to be understood as being modified by the term “about” unless specifically stated otherwise.

### Structure for an Optical Device

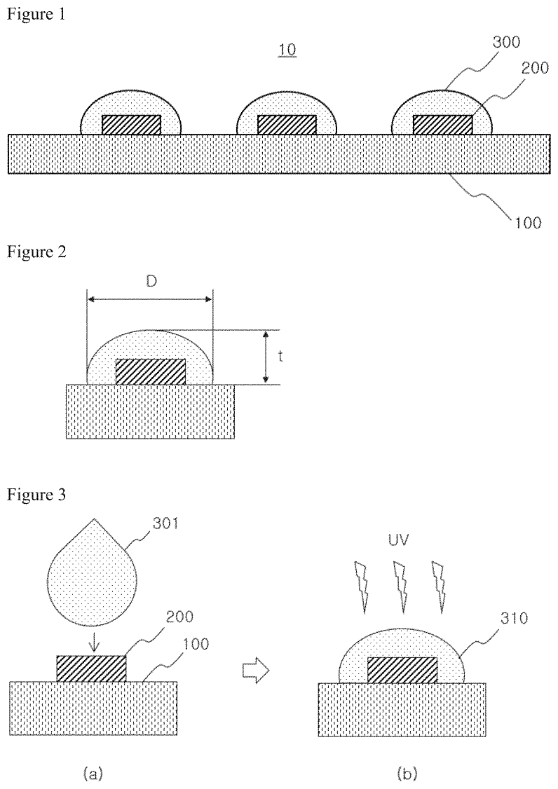

FIG. 1 shows a cross-sectional view of a structure for an optical device according to an embodiment. Referring to FIG. 1, the structure for an optical device according to the present invention comprises a substrate layer (100); a light emitting element (200) formed on the substrate layer (100); and a protective layer (300) surrounding the light emitting element (200).

The substrate layer may be, for example, a circuit board. Specifically, the substrate layer may comprise a circuit composed of a conductive material such as aluminum or copper. In addition, the substrate layer may further comprise an insulation material. The insulation material may comprise, for example, such polymer as polyimide, epoxy, and polyester, such ceramic as aluminum nitride, boron nitride, silicon nitride, alumina, or glass.

One or more light emitting elements are formed on the substrate layer. The light emitting element may be mounted on the substrate layer by, for example, die bonding. In addition, the light emitting element may be electrically connected to the circuit of the substrate layer by a conductive wire, for example, a bonding wire,

The light emitting element may be a light emitting diode (LED) chip. As an example, the light emitting element may be a mini-LED chip, the size of which may be specifically 1 mm or less, 500 μm or less, 300 μm or less, or 200 μm or less, and more specifically 100 μm to 200 μm. As another example, the light emitting element may be a micro-LE) chip, the size of which may be specifically less than 100 μm, and more specifically 5 μm to less than 100 μm.

The protective layer is formed on the substrate layer to surround the light emitting element. As such, the protective layer serves as an encapsulant of the light emitting element to protect the light emitting element from external heat or moisture. The shape of the protective layer is not particularly limited, but it may have, for example, a hemispherical shape such as a dome.

In particular, the protective layer may have a lens shape to diffuse light; thus, the protective layer may function as an encapsulant and a lens at the same time.

According to an example, the protective layer may have a certain level of a diameter to thickness ratio, so that its function as a lens may be further enhanced.

FIG. 2 shows the diameter (D) and thickness (t) of a protective layer in the structure for an optical device. Referring to FIG. 2, the protective layer may satisfy the following Relationship (1).

7.0>D/t (1)

Here, D is the diameter (mm) of the protective layer, and t is the thickness (mm) of the protective layer.

The value of D/t in Relationship (1) may be, for example, less than 7.0, 6.5 or less, 6.0 or less, less than 6.0, 5.5 or less, or 5.0 or less. In addition, the value of D/t in Relationship (1) may be at least a certain level, for example, 1.0 or more, 2.0 or more, 3.0 or more, 4.0 or more, 4.5 or more, 5.0 or more, 5.5 or more, or 6.0 or more.

In addition, the protective layer may have a refractive index of at least a certain level. For example, it may have a refractive index of 1.2 or more, 1.3 or more, 1.4 or more, or 1.5 or more. Specifically, the protective layer may have a refractive index of 1.5 or more. In addition, the refractive index of the protective layer may be 3.0 or less, 2.5 or less, 2.0 or less, 1.7 or less, or 1.6 or less.

The protective layer is capable of serving not only to protect or seal an optical device such as a mini-LED chip from external heat or moisture, but also to improve such optical characteristics as brightness and contrast ratio of light emitted from the LED through the light diffusion effect attributable to improvement in the refractive index.

In the structure for an optical device of the present invention, the protective layer comprises a photocured material of a photocurable siloxane resin composition.

According to an embodiment, the photocurable siloxane resin composition comprises a polysiloxane to which a functional group that reacts with an acid has been introduced, uses a photoacid generator instead of a thermal acid generator, and is a solvent-free type with controlled viscosity, whereby it is possible to obtain a protective layer with excellent pattern reproducibility and light diffusion characteristics while shortening the curing time.

In contrast, the conventional protective layers are generally obtained by introducing a thermal acid generator or a thermal base generator to cure an epoxy or by crosslinking a double bond in the presence of a platinum catalyst. However, in these conventional methods, it is difficult to reproduce the shape of a cured material because the heat flow is not controlled during the process, and there is a problem in that it takes a long time for curing or that discoloration occurs depending on the amount of the platinum catalyst used.

FIG. 3 shows a process for preparing a structure for an optical device according to an embodiment.

Referring to FIG. 3, in the structure for an optical device, a photocurable siloxane resin composition (301) is applied to a light emitting element (200) formed on a substrate layer (100) and is photocured (e.g., by UV irradiation) to form a protective layer surrounding the light emitting element.

The process for preparing a structure for an optical device according to an embodiment comprises (1) preparing a substrate layer and a light emitting element formed on the substrate layer; (2) applying a photocurable siloxane resin composition to the light emitting element; and (3) irradiating light to the photocurable siloxane resin composition to form a protective layer surrounding the light emitting element.

The light irradiation may be carried out by irradiating, for example, ultraviolet rays (e.g., UV-A, UV-B, UV-C) at an exposure dose of about 10 mJ/cm² to 5,000 mJ/cm² for 5 seconds to 30 seconds.

Photocurable Siloxane Resin Composition

The photocurable siloxane resin composition comprises (A) a polysiloxane having a functional group that reacts with an acid; (B) a photoacid generator; and (C) a solvent-free type diluent having a functional group that reacts with an acid. The photocurable siloxane resin composition may optionally further comprise (D) an adhesion supplement or other additives.

The polysiloxane may have a refractive index of at least a certain level. For example, it may have a refractive index of 1.2 or more, 1.3 or more, 1.4 or more, or 1.5 or more. Meanwhile, the refractive index of the polysiloxane may be 3.0 or less, 2.5 or less, 2.0 or less, 1.7 or less, or 1.6 or less. In addition, the photocurable siloxane resin composition may also have the same or similar refractive index as that of the polysiloxane, which is a main component thereof.

According to an embodiment, the polysiloxane has a viscosity of 10,000 cP to 50,000 cP at 25° C. For example, the viscosity of the polysiloxane may be 10,000 cP or more, 15,000 cP or more, 20,000 cP or more, 25,000 cP or more, or 30,000 cP or more, and also 50,000 cP or less, 45,000 cP or less, 40,000 cP or less, or 35,000 cP or less at 25° C. The viscosity may be a value of the polysiloxane measured with a Brookfield viscometer. When the viscosity is in the above range, it is advantageous for obtaining a reproducible structure by adjusting the viscosity of the entire composition within a preferred range to improve the problem caused by the layer being pulled up or flowing during the process dotting operation.

The photocurable siloxane resin composition is prepared in a solvent-free type. For example, the content of a solvent in the composition of the present invention may be less than 4.0% by weight, specifically, less than 3.0% by weight, less than 2.0% by weight, or less than 1.0% by weight. If the solvent content is outside the above range, bubbles may be generated by the vapor of the solvent during the process in which the composition is used, and it may be difficult to form a uniformly shaped pattern and may cause problems in the process. Meanwhile, any solvent that may be contained in the composition of the present invention in a trace amount may be a residual solvent that cannot be removed during the synthesis of the raw materials.

While the composition of the present invention does not use a solvent, a diluent having a functional group that reacts with an acid is used to sufficiently dissolve a photoacid generator and the like to adjust the viscosity.

In addition, the viscosity of the photocurable siloxane resin composition may be affected by the viscosity of the components such as polysiloxane contained therein. For example, the viscosity of the photocurable siloxane resin composition may be 10,000 cP or more, 15,000 cP or more, 20,000 cP or more, 25,000 cP or more, or 30,000 cP or more, and also 50,000 cP or less, 45,000 cP or less, 40,000 cP or less, or 35,000 cP or less at 25° C. As a specific example, the photocurable siloxane resin composition may have a viscosity of 20,000 cP to 40,000 cP at 25° C.

In the photocurable siloxane resin composition, a functional group that reacts with an acid has been introduced to a polysiloxane, and a photoacid generator instead of a thermal acid generator that takes a long time to cure is used, thereby shortening the curing time and satisfying pattern reproducibility and physical properties. In addition, the photocurable siloxane resin composition is a solvent-free type, and the acid generated by light acts as a catalyst to shorten the process time. Since it does not require the use of a platinum catalyst, there is no concern about discoloration due to platinum adsorption during the process. In addition, the photocurable siloxane resin composition has a controlled viscosity, thereby solving the problem that it is difficult for the conventional compositions to increase the thickness due to the heat flow in the direction of gravity. It is also possible to achieve an excellent diameter to thickness ratio.

Hereinafter, each component of the photocurable siloxane resin composition will be explained in detail.

(A) Polysiloxane

The photocurable siloxane resin composition comprises a polysiloxane having a functional group that reacts with an acid.

As an example, the polysiloxane may have an average structure represented by the following Formula 1:

R¹ₚR²_{q}SiO_{(4-p-q)/2} [Formula 1]

In Formula 1, p and q satisfy 1≤p+q≤3 and 0≤q, p:q is 3:1 to 1:0, R¹ contains a cyclic ether group having 2 to 6 carbon atoms, and R² contains an aryl group or an aralkyl group having 6 to 15 carbon atoms.

For example, in Formula 1, p may be 0.75 or more or 1 or more, and 3 or less or 2.5 or less. q may be 0 or more or 0.25 or more, and 0.75 or less or 0.5 or less. Specifically, in Formula 1, p may be 0.75 to 3, and q may be 0 to 0.75.

The cyclic ether group may have 2 to 6 carbon atoms and comprise an oxygen atom between the carbon chains. The number of carbon atoms in the cyclic ether group may be 2 to 6, 2 to 5, or 2 to 4. It may comprise 1 to 3 oxygen atoms. Specific examples of R¹ containing the cyclic ether group include epoxy, glycidyl, glycidoxy, glycidoxymethyl, glycidoxyethyl, glycidoxypropyl, 3,4-epoxycyclohexylethyl, and the like.

The aryl group or aralkyl group may have 6 to 15 carbon atoms and comprise an aromatic hydrocarbon. The number of carbon atoms in the aryl group or aralkyl group may be 6 to 15, 6 to 12, 6 to 10, or 6 to 8. Specific examples of the aryl group or aralkyl group may include phenyl, benzyl, phenethyl, tolyl, naphthyl, naphthylmethyl, naphthylethyl, and the like. These may be unsubstituted or substituted with one or more halogen, amino, alkyl, or the like.

In Formula 1, the molar ratio of R¹ to R² may be 75:25 to 100:0, 75:25 to 90:10, 75:25 to 80:20, 80:20 to 100:0, 85:15 to 100:0, or 80:20 to 90:10.

Specifically, the polysiloxane may contain (a-1) a structural unit derived from a silane compound containing a cyclic ether group, and (a-2) a structural unit derived from a silane compound containing an aryl group or an aralkyl group.

(a-1) Structural Unit Derived from a Silane Compound Containing a Cyclic Ether Group

The structural unit (a-1) contains a cyclic ether group and serves to form a network through a reaction with an acid upon curing, thereby enhancing the durability and optical properties.

The structural unit (a-1) is derived from a silane compound containing a cyclic ether group. The silane compound containing a cyclic ether group may be at least one silane compound represented by the following Formula 2a or a hydrolysate thereof:

R¹ₐSi(OR³)₄₋ₐ [Formula 2b]

In Formula 2a, a is an integer of 1 to 3, R¹ each contains a cyclic ether group having 2 to 6 carbon atoms, and R³ is an alkyl group having 1 to 6 carbon atoms.

The cyclic ether group may have 2 to 6 carbon atoms and comprise an oxygen atom between the carbon chains. The number of carbon atoms in the cyclic ether group may be 2 to 6, 2 to 5, or 2 to 4. It may comprise 1 to 3 oxygen atoms. Specific examples of R¹ containing the cyclic ether group include epoxy, glycidyl, glycidoxy, glycidoxymethyl, glycidoxyethyl, glycidoxypropyl, 3,4-epoxycyclohexylethyl, and the like.

The alkyl group may have 1 to 6 carbon atoms, for example, 1 to 5, 1 to 4, or 1 to 3 carbon atoms. Specific examples of the alkyl group may include methyl, ethyl, n-propyl, i-propyl, n-butyl, i-butyl, t-butyl, pentyl, hexyl, and the like.

In Formula 2a, the compound may be a tetrafunctional silane compound where a is 0, a trifunctional silane compound where a is 1, a difunctional silane compound where a is 2, or a monofunctional silane compound where a is 3.

Specific examples of the silane compound containing a cyclic ether group include 3-glycidoxypropy1-trimethoxysilane(γ-glycidoxypropyl-trimethoxy silane), 3-glycidoxypropyl-methyIdimethoxysilane, 3-glycidoxypropyl-triethoxysilane, 3-glycidoxypropyl-methyl diethoxysilane, β-(3,4-epoxycyclohexyl)ethyltrimethoxysilane, and the like.

The amount of the structural unit (a-1) may be 51 to 100% by mole, preferably 75 to 100% by mole, based on the total moles of the structural units constituting the polysiloxane. Within the above content range, it is advantageous for having sufficient adhesion and hardness.

(a-2) Structural Unit Derived from a Silane Compound Containing an Aryl Group or an Aralkyl Group

The structural unit (a-2) contains an aryl group or an aralkyl group and may increase the refractive index, thereby enhancing the light diffusion characteristics.

The structural unit (a-2) is derived from a silane compound containing an aryl group or an aralkyl group. The silane compound containing an aryl group or an aralkyl group may be at least one silane compound represented by the following Formula 2b or a hydrolysate thereof.

R²_{b}Si(OR³)_{4-b} [Formula 2b]

In Formula 2b, b is an integer of 1 to 3, R² each contains an aryl group or an aralkyl group having 6 to 15 carbon atoms, and R³ is an alkyl group having 1 to 6 carbon atoms.

The aryl group or aralkyl group may have 6 to 15 carbon atoms and comprise an aromatic hydrocarbon. The number of carbon atoms in the aryl group or aralkyl group may be 6 to 15, 6 to 12, 6 to 10, or 6 to 8. Specific examples of the aryl group or aralkyl group may include phenyl, benzyl, phenethyl, tolyl, naphthyl, naphthylmethyl, naphthylethyl, and the like. These may be unsubstituted or substituted with one or more halogen, amino, alkyl, and the like.

The alkyl group may have 1 to 6 carbon atoms, for example, 1 to 5, 1 to 4, or 1 to 3 carbon atoms. Specific examples of the alkyl group may include methyl, ethyl, n-propyl, i-propyl, n-butyl, i-butyl, t-butyl, pentyl, hexyl, and the like.

Specific examples of the structural unit (a-2) include phenyltrimethoxysilane, phenyltriethoxysilane, diethoxydiphenylsilane, dimethoxydiphenylsilane, N-phenyl-3-aminopropyltrimethoxysilane, p-chlorophenyltrimethoxysilane, p-bromophenyltrimethoxvsilane, diethoxymethylphenylsilane, dimethoxymethylphenylsilane, triethoxytolylsilane, 1-naphthyltrimethoxysilane, m-aminophenyltrimethoxysilane, and the like.

The amount of the structural unit (a-2) may be 0 to 49% by mole, preferably 0 to 25% by mole, based on the total moles of the structural units constituting the polysiloxane. Within the above range, it is advantageous for the increase in refractive index, improvement in yellow index (Y. I.) value, and UN stability.

Preparation and Characteristics of the Polysiloxane

The silane compound containing a cyclic ether group and the silane compound containing an aryl group or an aralkyl group as exemplified above may be combined to be used in the preparation of the polysiloxane. Specifically, the silane compound of Formula 2a and the silane compound of Formula 2b may be combined to be used in the preparation of the polysiloxane.

The conditions for obtaining a hydrolysate or a condensate of these silane compounds for the preparation of the polysiloxane are not particularly limited. For example, the silane compound of Formula 2a and the silane compound of Formula 2b are optionally diluted with a solvent such as ethanol, 2-propanol, acetone, butyl acetate, or the like, and water and an acid (e.g., hydrochloric acid, acetic acid, nitric acid, or the like) or a base (e.g., ammonia, triethylamine, cyclohexylamine, tetramethylammonirum hydroxide, or the like) as a catalyst are added thereto, followed by stirring the mixture to obtain the desired hydrolysate or condensate thereof.

The type and amount of the solvent or the acid or base catalyst are not particularly limited. In addition, the hydrolytic polymerization reaction may be carried out at a low temperature of 20° C. or lower. Alternatively, the reaction may be expedited by heating or refluxing.

The required reaction time may be adjusted depending on the type and concentration of the silane compounds, reaction temperature, and the like. For example, it usually takes 15 minutes to 30 days for the reaction to be carried out until the molecular weight of the condensate thus obtained becomes approximately 500 to 50,000. But it is not limited thereto.

The weight average molecular weight (Mw) of the polysiloxane may be 2,000 to 10,000, preferably, 3,000 to 5,000. Within the above molecular weight range, it is advantageous for achieving a desired viscosity when the composition is prepared without a solvent.

In the present specification, the weight average molecular weight refers to a weight average molecular weight measured by gel permeation chromatography (GPC, eluent: tetrahydrofuran) and referenced to a polystyrene standard. Typically, it does not accompany a unit, but it may be understood to have a unit of g/mole or Da.

The solids content excluding solvents in the polysiloxane may be 96% by weight to 99.9% by weight. Within the above range, it is advantageous for controlling the solvent content in the entire composition within a preferred range to prepare it as a solvent-free type.

The polysiloxane may have a viscosity of 10,000 cP to 50,000 cP at 25° C. The viscosity may be a value of the polysiloxane measured with a Brookfield viscometer. When the viscosity is within the above range, it is possible to adjust the viscosity of the entire composition within a preferred range and advantageous for obtaining a reproducible structure by improving the problem caused by the layer being pulled up or flowing during the process dotting operation.

The content of the polysiloxane may be 70 to 99% by weight, preferably 80 to 95% by weight, based on the total weight of the photocurable siloxane resin composition. The content may be based on the content excluding solvents. Within the above content range, it is advantageous for obtaining a structure having excellent optical properties and a high degree of curing.

(B) Photoacid Generator

The photocurable siloxane resin composition comprises a photoacid generator.

The photoacid generator generates an acid by irradiation with light to crosslink a polysiloxane having a functional group that reacts with an acid.

In addition, the photoacid generator serves to initiate the polymerization of monomers that can be cured by visible light, ultraviolet radiation, deep-ultraviolet radiation, or the like.

Examples of the photoacid generator include an onium salt compound, a halogen-containing compound, a diazoketone compound, a diazomethane compound, a sulfone compound, a sulfone ester compound, and a sulfonimide compound, but it is not particularly limited thereto.

Examples of the onium salt compound include iodonium salts, sulfonium salts, phosphonium salts, diazonium salts, pyridinium salts, and the like. Specific examples of the onium salt compound include at least one selected from the group consisting of diphenyliodonium triflate, diphenyliodonium pyrenesulfonate, diphenyliodoniurn dodecylbenzenesulfonate, triphenylsulfonium triflate, triphenylsulfoniurn hexafluoroantimnonate, and triphenylsulfoniurn naphthalenesulfonate.

Examples of the halogen-containing compound include haloalkyl group-containing hydrocarbon compounds and haloalkyl group-containing heterocyclic compounds. Specific examples of the halogen-containing compound include 1,10-dibromo-n-decane, 1,1-bis(4-chlorophenyl)-2,2,2-trichloroethane, phenyl-bis(trichloronethyl)-s-triazine, 4-methoxy phenyl-bis(trichloronethyl)-s-triazine, styryl-bis(trichloronethyl)-s-triazine, naphthyl-bis(trichloromethyl)-s-triazine, and the like.

Specific examples of the diazonethane compound include bis(trifluoromethylsulfonyl)diazomethane, bis(cyclohexylsulfonyl)diazomethane, bis(phenylsulfonyl)diazomethane, and the like.

Specific examples of the sulfone ester compound include alkylsulfonic acid esters, haloalkylsulfonic acid esters, arylsulfonic acid esters, and ininosulfonates. Specific examples of the preferred sulfonic acid compound include benzointosylate, pyrogallol trifluoromethanesulfonate, o-nitrobenzyl trifluoromethanesulfonate, o-nitrobenzyl p-toluenesulfonate, and the like.

Specific examples of the sulfonimide compound include N-(trifluoronethylsulfonyioxy)succinimide, N-(trifluoromethyIsulfonyloxv)phthalimide, N-(trifluoromethylsulfonyloxy)diphenymaleimide, N-(trifluoronethylsulfonyloxy)bicyclo[2 2.1]hepto-5-ene-2,3-dicarboxyinide, N-(trifluoronethylsulfonyloxy)naphthylimide, and the like.

The content of the photoacid generator may be 0.01 to 10 parts by weight based on 100 parts by weight of the content of the polysiloxane. The content may be based on the content excluding solvents. Within the above content range, it is advantageous for achieving optical properties such as transparency and a high degree of curing of the composition. Specifically, if the content of the photoacid generator is less than 0.01 part by weight, the degree of curing may be insufficient. If it exceeds 10 parts by weight, discoloration or cracking in the pattern due to shrinkage during curing may occur. Preferably, the content of the photoacid generator may be 0.1 to 6 parts by weight based on 100 parts by weight of the content of the polysiloxane.

In addition, the content of the photoacid generator may be 0.01 to 10 parts by weight based on the total weight of the photocurable siloxane resin composition exclusive of solvents.

(C) Diluent

The photocurable siloxane resin composition comprises a solvent-free type diluent having a functional group that reacts with an acid.

The diluent serves to uniformly dissolve the photoacid generator without using a solvent while it is not vaporized during the process.

The functional group in the diluent, which reacts with an acid, may be, for example, a cyclic ether group having 2 to 6 carbon atoms such as epoxy or glycidyl.

For example, the diluent may be a monomer having an epoxy group or a glycidyl group. Specifically, the diluent may be at least one selected from the group consisting of (3,4-epoxycyclohexyl)methyl (meth)acrylate, glycidyl (meth)acrylate, and allyl glycidyl ether. More specifically, the diluent may be (3,4-epoxycyclohexyl)methyl acrylate, or glycidyl methacrylate.

The content of the diluent may be 0.01 to 10 parts by weight based on 100 pails by weight of the content of the polysiloxane. The content may be based on the content excluding solvents. Within the above content range, it is advantageous for enhancing the diameter to thickness ratio (i.e., aspect ratio) and pattern reproducibility of the composition. Specifically, if the content of the diluent is less than 0.01 part by weight, the photoacid generator may not be uniformly dissolved. If it exceeds 10 parts by weight, the viscosity of the composition may be lowered, thereby reducing the diameter to thickness ratio. Preferably, the content of the diluent may be 0.1 to 6 parts by weight based on 100 parts by weight of the content of the polysiloxane.

Specifically, the content of the diluent may be 0.1 to 10 parts by weight based on 100 parts by weight of the content of the polysiloxane. It may be 30 parts by weight or more, 40 parts by weight or more, or 50 parts by weight or more, based on 100 parts by weight of the total content of the photoacid generator and the diluent.

In addition, the content of the diluent may be 0.01 to 10 parts by weight based on the total weight of the photocurable siloxane resin composition exclusive of solvents.

(D) Adhesion Supplement

The photocurable siloxane resin composition of the present invention may further comprise an adhesion supplement to enhance the adhesiveness to a substrate layer, if necessary.

The adhesion supplement may have at least one reactive group selected from the group consisting of a carboxyl group, an acryloyl group, a methacryloyl group, an isocyanate group, an amino group, a mercapto group, a vinyl group, an epoxy group, and a combination thereof.

The kind of the adhesion supplement is not particularly limited. It may be at least one selected from the group consisting of trimethoxysilyl benzoic acid, γ-methacryloxypropyltrimethoxysilane, vinyltriacetoxysilane, vinyltrimethoxysilane, γ-isocyanatopropyltriethoxvsilane, γ-glycidoxypropyltrimethoxysilane, γ-glycidoxypropyltriethoxysilane, N-phenylaminopropyItrimethoxysilane, and β-(3,4-epoxycyclohexyl)ethyltrimethoxysilane. Preferred is γ-glycidoxypropyltrimethoxy silane, γ-glycidoxypropyltriethoxysilane, or N-phenylaminopropyltrimethoxysilane, which is capable of enhancing the film retention rate and is excellent in the adhesiveness to a substrate layer.

The content of the adhesion supplement may be 0.01 to 10 parts by weight based on 100 parts by weight of the content of the polysiloxane. The content may be based on the content excluding solvents. Within the above content range, it is advantageous for further enhancing the adhesiveness of the composition. Specifically, if the content of the adhesion supplement is less than 0.01 part by weight, the adhesiveness to a substrate layer may be lowered. If it exceeds 10 parts by weight, it may reduce the degree of curing. Preferably, the content of the adhesion supplement may be 0.1 to 3 parts by weight based on 100 parts by weight of the content of the polysiloxane.

In addition, the content of the adhesion supplement may be 0.01 to 10 parts by weight based on the total weight of the photocurable siloxane resin composition exclusive of solvents.

In addition, the photocurable siloxane resin composition may further comprise other additives such as an antioxidant and a stabilizer as long as the physical properties of the composition are not adversely affected.

### Mode for the Invention

Hereinafter, the present invention will be described in more detail with reference to the following examples. However, these examples are provided to illustrate the present invention, and the scope of the present invention is not limited thereto only.

Preparation Example 1: Preparation of Polysiloxane A-1

A reactor equipped with a reflux condenser was charged with 58.6 parts by weight of (3-glycidoxy propyl)trimethoxysilane, 16.4 parts by weight of phenyltrimethoxysilane, 20 parts by weight of pure water, and 5 parts by weight of tetrahydrofuran (TIF), followed by refluxing and vigorously stirring the mixture for 5 hours in the presence of 0.1 part by weight of an oxalic acid catalyst.

After the reaction solution was cooled, water was removed in a vacuum oven at room temperature (25° C.) and a minimum pressure of −760 mmHg. It was then transferred to a tray and further volatilized under a reduced pressure at 40° C. to prepare polysiloxane A-1.

The polysiloxane was measured for the weight average molecular weight (Mw) by gel permeation chromatography (GPC), the viscosity with a Brookfield viscometer, and the moisture content by the Volumetric KF moisture crystallization method, which was converted to a solids content. They are shown in Table 1 below.

Preparation Examples 2 to 9: Preparation of Polysiloxane A-2 to A-9

The procedures of Preparation Example 1 were repeated according to the content ratio of the monomers shown in Table 1 to prepare polysiloxane A-2 to A-9. The weight average molecular weight, viscosity, and solids content are shown. However, non-uniform precipitation occurred during the synthesis of polysiloxane A-9.

Preparation Example 3: Preparation of Acrylic Copolymer A-10

The procedures of Preparation Example 1 were repeated according to the content ratio of the monomers shown in Table 2 below to prepare acrylic copolymer A-10. The weight average molecular weight, viscosity, and solids content are shown.

TABLE 1

| | Monomer | | | | |
|---|---|---|---|---|---|
| | (% by mole) | | Solids content | Viscosity | |
| Polysiloxane | GPTMS | PTMS | (% by weight) | (cP at 25° C.) | Mw |
| A-1 | 75 | 25 | 99.72 | 29,000 | 3,538 |
| A-2 | 75 | 25 | 99.72 | 46,000 | 5,213 |
| A-3 | 100 | 0 | 99.70 | 7,000 | 4,969 |
| A-4 | 75 | 25 | 95.20 | 22,000 | 6,350 |
| A-5 | 75 | 25 | 99.75 | 12,000 | 5,203 |
| A-6 | 75 | 25 | 99.62 | 53,000 | 5,543 |
| A-7 | 75 | 25 | 99.70 | 66,000 | 7,325 |
| A-8 | 100 | 0 | 99.67 | 36,000 | 4,267 |
| A-9 | 50 | 50 | — | — | — |

GPTMS: (3-glycidoxypropyl)trimethoxysilane,
PTMS: phenyltrimethoxysilane

TABLE 2

| Acrylic | | | | | Solids content | Viscosity | |
|---|---|---|---|---|---|---|---|
| copolymer | PMI | STY | MAA | 4-HBAGE | (% by weight) | (cP at 25° C.) | Mw |
| A-10 | 51 | 9 | 25 | 15 | 31.7 | 93 | 9,111 |

PMI: N-phenylmaleimide,
Sty: styrene
4-HBAGE: 4-hydroxybutylacrylate glycidyl ether,
MAA: methacrylic acid

### Example 1

Step 1: Preparation of a photocurable siloxane resin composition

5.6 parts by weight of the photoacid generator (B) was diluted with 5.6 parts by weight of the diluent (C-1), which was then added to 100 parts by weight of the polysiloxane (A-1) of Preparation Example 1. The resultant was mixed using a shaker for 8 hours to thereby prepare a liquid-phase composition of Example 1.

Step 2: Preparation of a structure for an optical device

The composition prepared in Step 1 above was applied in a small dome shape with a diameter of about 3 mm and a thickness of 500 μm or more on a printed circuit board (PCB) provided with mini-LED chips using a pipette. Thereafter, it was sufficiently cured by exposure for 12 seconds at an exposure dose of 3 J/cm² with an exposure machine (Heraeus Noblelight Benchtop Conveyor/UV-A with a standard intensity of 2,500 mW) to form a lens-shaped protective layer. As a result, a structure for an optical device was obtained in which mini-LED chips on a PCB were surrounded by a lens-shaped protective layer.

### Examples 2 to 7 and Comparative Examples 1 to 10

The procedures of Step 1 of Example 1 were repeated according to the compositions of Examples 2 to 7 and Comparative Examples 1 to 10 shown in Table 3 below to prepare liquid-phase compositions. The compositions thus obtained were each used to prepare a structure for an optical device according to the procedures of Step 2 of Example 1.

TABLE 3
Components in the composition and parts by weight thereof

| | | | Photoacid | | Photobase | | | | Adhesion | |
|---|---|---|---|---|---|---|---|---|---|---|
| | Binder | | generator | | generator | | Diluent | | supplement | |
| Ex. 1 | A-1 | 100 | B | 5.6 | — | — | C-1 | 5.6 | — | — |
| Ex. 2 | A-5 | 100 | B | 5.6 | — | — | C-1 | 5.6 | — | — |
| Ex. 3 | A-1 | 100 | B | 5.7 | — | — | C-1 | 5.7 | D | 2.3 |
| Ex. 4 | A-1 | 100 | B | 2.7 | — | — | C-1 | 2.7 | D | 1.1 |
| Ex. 5 | A-1 | 100 | B | 5.5 | — | — | C-2 | 4.4 | — | — |
| Ex. 6 | A-2 | 100 | B | 5.5 | — | — | C-2 | 4.4 | — | — |
| Ex. 7 | A-8 | 100 | B | 5.5 | — | — | C-2 | 4.4 | — | — |
| C. Ex. 1 | A-4 | 100 | B | 5.7 | — | — | C-1 | 5.7 | D | 2.3 |
| C. Ex. 2 | A-3 | 100 | B | 1 | — | — | — | — | D | 2.1 |
| C. Ex. 3 | A-6 | 100 | B | 5.6 | — | — | C-1 | 5.6 | — | — |
| C. Ex. 4 | A-7 | 100 | B | 5.7 | — | — | C-1 | 5.7 | D | 2.3 |
| C. Ex. 5 | A-1 | 100 | — | — | E | 3.3 | C-1 | 5.6 | D | 2.2 |
| C. Ex. 6 | A-1 | 100 | — | — | E | 7.5 | C-1 | 12.5 | D | 5 |
| C. Ex. 7 | A-1 | 100 | B | 5.6 | — | — | C-3 | 5.6 | — | — |
| C. Ex. 8 | A-1 | 100 | B | 5.6 | — | — | C-4 | 5.6 | — | — |
| C. Ex. 9 | A-1 | 100 | B | 5.6 | — | — | C-5 | 5.6 | — | — |
| C. Ex. 10 | A-10 | 100 | B | 5.6 | — | — | C-5 | 5.6 | — | — |

TABLE 4

| | Component/trade name |
|---|---|
| Photoacid | hexafluorophosphate type |
| generator (B) | (PAG-30201, DKSH) |
| Photobase | 9-anthrylmethyl N,N-diethylcarbamate |
| generator (E) | (WPBG-018, Wako) |
| Diluent (C-1) | (3,4-epoxycyclohexyl)methyl acrylate |
| | (Aldrich) |
| Diluent (C-2) | glycidyl methacrylate |
| Diluent (C-3) | methyl methacrylate |
| Diluent (C-4) | methacrylic acid |
| Diluent (C-5) | styrene |
| Adhesion | (3-glycidoxypropyl)trimethoxysilane |
| supplement (D) | |

### Test Example 1

The following tests were carried out on the compositions obtained in Step 1 of the Examples and Comparative Examples.

(1) Evaluation of viscosity of the composition

The viscosity of the composition was measured with a Brookfield viscometer at 25° C.

(2) Evaluation of solvent-free preparation

It was checked whether the composition was completely transparent when observed with the naked eyes.
o: No solid substances were observed with the naked eyes
x: Solid substances were observed with the naked eyes

(3) Evaluation of refractive index

The refractive index of the composition was measured. As a result, the refractive indices of the compositions of Examples 1 to 7 were all measured to be 1.5 or more.

### Test Example 2

The following tests were carried out on the protective layers of the structures for optical devices obtained in Step 2 of the Examples and Comparative Examples.

(1) Evaluation of bubbles

The presence or absence of bubbles inside the protective layer was checked with an optical microscope.
o: No bubbles were observed
x: Bubbles were observed

(2) Evaluation of pattern shape

The pattern shape of the protective layer was checked with an optical microscope.
o: Regular dome shape
x: Irregular dome shape

(3) Measurement of reproducibility

The diameter and thickness of five protective layers were measured with a vernier caliper, and the reproducibility was evaluated by calculating a diameter to thickness ratio (aspect ratio).
o: Reproducible
x: Not reproducible

(4) Measurement of the degree of curing

The top of the protective layer was pressed with a fingernail in the perpendicular direction, and the presence or absence of nail marks and breakage of the protective layer were checked.
o: No marks when pressed with a fingernail
x: Marks or breakage occurred when pressed with a fingernail

(5) Measurement of yellow index (Y.I.)

The yellow index (Y.I.) of the protective layer was measured with a spectrophotometer (SD4000, manufactured by NIPPON DENSHOKU).
o: Y.I. of 1.0 or less (see FIG. 5a)
x: Y.I. of greater than 1.0 (see FIG. 5b)

(6) Evaluation of diameter to thickness ratio (aspect ratio)

Referring to FIG. 2, the diameter (D) and thickness (t) of the protective layer were measured with a vernier caliper, and the diameter to thickness ratio (D/t) was calculated based thereon.

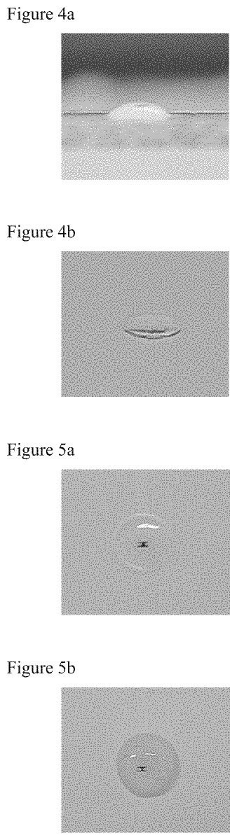

In addition, the diameter to thickness ratio was evaluated according to the following criteria.
o: When the diameter was 3.0±0.1 mm, and the thickness was more than 500 μm (see FIG. 4a)
Δ: When the diameter was 3.0±0, 1 mm, and the thickness was 200 to 500 μm
x: When the diameter was 3.0±0.1 mm, and the thickness was less than 200 μm (see FIG. 4b)

The test results are shown in the tables below.

TABLE 5

| | Composition | | Protective layer | | | | |
|---|---|---|---|---|---|---|---|
| | Viscosity | Solvent- | Evaluation | Pattern | Reproduce- | Degree of | |
| | (cP) | free | of bubbles | shape | bility | curing | Y.I. |
| Ex. 1 | 25,700 | ◯ | ◯ | ◯ | ◯ | ◯ | ◯ |
| Ex. 2 | 10,500 | ◯ | ◯ | ◯ | ◯ | ◯ | ◯ |
| Ex. 3 | 25,400 | ◯ | ◯ | ◯ | ◯ | ◯ | ◯ |
| Ex. 4 | 27,100 | ◯ | ◯ | ◯ | ◯ | ◯ | ◯ |
| Ex. 5 | 26,100 | ◯ | X | ◯ | ◯ | X | ◯ |
| Ex. 6 | 41,400 | ◯ | ◯ | ◯ | ◯ | ◯ | ◯ |
| Ex. 7 | 32,000 | ◯ | ◯ | ◯ | ◯ | ◯ | ◯ |
| C. Ex. 1 | 19,400 | ◯ | X | ◯ | ◯ | ◯ | X |
| C. Ex. 2 | 6,600 | ◯ | ◯ | X | ◯ | ◯ | ◯ |
| C. Ex. 3 | 47,200 | ◯ | ◯ | X | X | X | ◯ |
| C. Ex. 4 | 57,700 | ◯ | ◯ | X | X | ◯ | ◯ |
| C. Ex. 5 | 25,900 | ◯ | ◯ | ◯ | ◯ | X | ◯ |
| C. Ex. 6 | 22,900 | ◯ | ◯ | ◯ | ◯ | X | ◯ |
| C. Ex. 7 | 25,500 | ◯ | ◯ | ◯ | ◯ | X | ◯ |
| C. Ex. 8 | 25,800 | X | — | — | — | — | ◯ |
| C. Ex. 9 | 25,400 | X | — | — | — | — | ◯ |
| C. Ex. 10 | 93 | X | X | X | X | ◯ | X |

TABLE 6

Evaluation of diameter to thickness ratio (aspect
ratio) of the protective layer

| | | | Diameter to | |
|---|---|---|---|---|
| | Diameter | Thickness | thickness | |
| | (mm) | (μm) | ratio | Evaluation |
| Ex. 1 | 3.1 | 520 | 5.96 | ◯ |
| Ex. 2 | 3.1 | 504 | 6.15 | ◯ |
| Ex. 3 | 3.0 | 527 | 5.69 | ◯ |
| Ex. 4 | 2.9 | 523 | 5.54 | ◯ |
| Ex. 5 | 2.9 | 525 | 5.52 | ◯ |
| Ex. 6 | 3.0 | 556 | 5.40 | ◯ |
| Ex. 7 | 3.0 | 528 | 5.68 | ◯ |
| C. Ex. 1 | 3.0 | 509 | 5.89 | ◯ |
| C. Ex. 2 | 3.2 | 137 | 23.36 | X |
| C. Ex. 3 | 2.9 | 553 | 5.24 | ◯ |
| C. Ex. 4 | 3.1 | 574 | 5.40 | ◯ |
| C. Ex. 5 | 3.1 | 515 | 6.02 | ◯ |
| C. Ex. 6 | 3.1 | 523 | 5.93 | ◯ |
| C. Ex. 7 | 2.9 | 319 | 9.09 | Δ |

As can be seen from the above test results, in the compositions prepared in Exarmples 1 to 7, in which a solvent-free diluent was used without a solvent, their transparent features were maintained, their viscosities were adjusted within a certain range, and their refractive indices were excellent. In addition, in the compositions of Examples 1 to 7, a functional group that reacts with an acid was introduced to a polysiloxane, and a photoacid generator was used, thereby shortening the curing time and satisfying the pattern reproducibility and physical properties Since a platinum catalyst does not have to be used, there is no concern about discoloration due to the platinum adsorption during the process. Accordingly, it was confirmed that the protective layers obtained through photocuring of the compositions in Examples 1 to 7 had no bubbles, had a regular and reproducible pattern shape, had an excellent degree of curing, and had a low yellow index. In particular, the protective layers of Examples 1 to 7 were excellent in the diameter to thickness ratio, so that they are capable of serving not only to protect mini-LED chips from external heat or moisture, but also to improve such optical characteristics as brightness and contrast ratio of light emitted from the LED chips through the light diffusion effect.

In contrast, since the compositions prepared in Comparative Examples 1 to 10 fell outside the preferred constitution of the present invention (that is, since the viscosity of the polysiloxane was outside a certain level, an acrylic binder was used, a thermal acid generator was employed, the diluent had no functional group that reacts with an acid, or a solvent was employed in a content exceeding a certain level), they were poor in at least one test.

1. A structure for an optical device, which comprises a substrate layer; a light emitting element formed on the substrate layer; and a protective layer surrounding the light emitting element,
wherein the protective layer comprises a photocured material of a photocurable siloxane resin composition, and
the photocurable siloxane resin composition comprises:
(A) a polysiloxane having a functional group that reacts with an acid;
(B) a photoacid generator; and
(C) a solvent-free type diluent having a functional group that reacts with an acid,
wherein the viscosity of the polysiloxane is 10,000 cP to 50,000 cP at 25° C., and the content of the solvent in the composition is less than 4.0% by weight.

2. The structure for an optical device of claim 1, wherein the photocurable siloxane resin composition has a viscosity of 20,000 cP to 40,000 cP at 25° C.

3. The structure for an optical device of claim 1, wherein the protective layer has a lens shape to diffuse light.

4. The structure for an optical device of claim 3, wherein the protective layer satisfies the following Relationship (1):
7.0>D/t (1)
wherein D is the diameter (mm) of the protective layer, and t is the thickness (mm) of the protective layer.

5. The structure for an optical device of claim 1, wherein the protective layer has a refractive index of 1.5 or more.

6. The structure for an optical device of claim 1, wherein the polysiloxane has an average structure represented by the following Formula 1:
R¹ₚR²_{q}SiO_{(4-p-q)/2} [Formula 1]
in the above Formula 1, p and q satisfy 1≤p+q≤3 and 0≤q, p:q is 3:1 to 1:0, R¹ contains a cyclic ether group having 2 to 6 carbon atoms, and R² contains an aryl group or an aralkyl group having 6 to 15 carbon atoms.

7. The structure for an optical device of claim 6, wherein the polysiloxane comprises (a-1) a structural unit derived from a silane compound containing a cyclic ether group and (a-2) a structural unit derived from a silane compound containing an aryl group or an aralkyl group.

8. The structure for an optical device of claim 7, wherein the silane compound containing a cyclic ether group is at least one silane compound represented by the following Formula 2a or a hydrolysate thereof:
R¹ₐSi(OR³)₄₋ₐ [Formula 2a]
in Formula 2a, a is an integer of 1 to 3, R¹ each contains a cyclic ether group having 2 to 6 carbon atoms, and R³ is an alkyl group having 1 to 6 carbon atoms.

9. The structure for an optical device of claim 7, wherein the silane compound containing an aryl group or an aralkyl group is at least one silane compound represented by the following Formula 2b or a hydrolysate thereof:
R²_{b}Si(OR³)_{4-b} [Formula 2b]
in Formula 2b, b is an integer of 1 to 3, R² each contains an aryl group or an aralkyl group having 6 to 15 carbon atoms, and R³ is an alkyl group having 1 to 6 carbon atoms.

10. The structure for an optical device of claim 1, wherein the content of the photoacid generator is 0.01 to 10 parts by weight based on 100 pails by weight of the content of the polysiloxane.

11. The structure for an optical device of claim 1, wherein the content of the diluent is 0.01 to 10 parts by weight based on 100 parts by weight of the content of the polysiloxane and 30 parts by weight or more based on 100 parts by weight of the total content of the photoacid generator and the diluent.

12. The structure for an optical device of claim 1, wherein the diluent is a monomer having an epoxy group or a glycidyl group.

13. The structure for an optical device of claim 1, wherein the light emitting element comprises a light emitting diode (LED) chip.

14. A process for preparing a structure for an optical device, which comprises:
preparing a substrate layer and a light emitting element formed on the substrate layer:
applying a photocurable siloxane resin composition to the light emitting element; and
irradiating light to the photocurable siloxane resin composition to form a protective layer surrounding the light emitting element,
wherein the photocurable siloxane resin composition comprises (A) a polysiloxane having a functional group that reacts with an acid; (B) a photoacid generator; and (C) a solvent-free type diluent having a functional group that reacts with an acid, wherein the viscosity of the polysiloxane is 10,000 cP to 50,000 cP at 25° C., and the content of the solvent in the composition is less than 4.0% by weight.

15. A photocurable siloxane resin composition, which comprises (A) a polysiloxane having a functional group that reacts with an acid; (B) a photoacid generator; and (C) a solvent-free type diluent having a functional group that reacts with an acid,
wherein the viscosity of the polysiloxane is 10,000 cP to 50,000 cP at 25° C., and the content of the solvent in the composition is less than 4.0% by weight.
